(19) United States
(12) Patent Application Publication
(10) Pub. No.: US 2026/0142672 A1
(43) Pub. Date: May 21, 2026

(54) POWER EFFICIENT FINE-GRAINED STORAGE ACCESS

(71) Applicant: NVIDIA Corporation, Santa Clara, CA (US)

(72) Inventors: Christopher J. Newburn, South Beloit, IL (US); Vikram Sharma Mailthody, Urbana, IL (US); Wen-Mei W. Hwu, Champaign, IL (US)

(21) Appl. No.: 19/347,306

(22) Filed: Oct. 1, 2025

Related U.S. Application Data
(60) Provisional application No. 63/721,952, filed on Nov. 18, 2024.

(51) Int. Cl. H03M 13/11; G06F 11/10; G06F 12/1027

(52) U.S. Cl. CPC H03M 13/1102; G06F 11/1044; G06F 12/1027

(57) ABSTRACT

The disclosure provides an apparatus, system, and method that increases the power efficiency of reading data from a storage device using, for example, reading guidance. The reading guidance allows software-defined data sizes that are beneficial for saving power when accessing data. The reading guidance can be the result of requesting agents providing additional contextual information with data requests that improves the power efficiency of obtaining the data for the data requests. In one example, an augmented data controller is disclosed that is configured to perform one or more operations associated with obtaining data from data storage for one or more requesting agents, wherein the operations include providing reading guidance to a storage controller associated with the data storage, wherein the reading guidance indicates one or more of an amount of data to read for a request or error checking procedures for data provided in response to the request.

### CROSS REFERENCE TO RELATED APPLICATION

This application claims the benefit of U.S. Provisional Application Ser. No. 63/721,952, filed by Christopher J. Newburn, et al., on Nov. 18, 2024, entitled “POWER EFFICIENT FINE-GRAINED STORAGE ACCESS”, which is commonly assigned with this application and incorporated herein by reference in its entirety. This application is also related to U.S. patent application Ser. No. 19/347,252 and U.S. patent application having Docket No. 24-MA-1417US04, both filed by Christopher J. Newburn, et al., on the same day as the present application.

### TECHNICAL FIELD

This application is directed, in general, to data storage, and more specifically, to obtaining data located in data storage using power-efficient, fine-grained accesses.

### BACKGROUND

A new class of applications executing on processors, such as a GPU or a CPU, are making fine-grained accesses, such as from each GPU thread, creating the need for new interfaces, a new infrastructure, and a new generation of storage devices and systems. The amount of data requested is typically greater than local memory and therefore is often stored on external memory devices connected to the processors. The IOPs rates demanded by these new applications, however, cannot be efficiently satisfied by today's solid state drives (SSDs) and/or non-volatile memory express solid state drive (NVMes) and their associated operating system (OS) software stack. Improvements to the processing of data requests and responses can be beneficial to maintaining maximal effective IOPs rates.

### SUMMARY

In one aspect, the disclosure provides an augmented data controller configured to perform one or more operations associated with obtaining data from data storage for one or more requesting agents. In one example, the operations include providing reading guidance to a storage controller associated with the data storage, wherein the reading guidance indicates error checking procedures for data provided in response to the request.

In another aspect, the disclosure provides a storage processing interface. In one example the storage processing interface includes: (1) a communication bus and (2) an augmented data controller connected to the communication bus and configured to perform one or more operations associated with obtaining data from data storage for a request from one or more requesting agents coupled to the communication bus. The operations include, for example, providing reading guidance to a storage controller associated with the data storage, wherein the reading guidance indicates error checking procedures for data provided in response to the request.

In yet another aspect, the disclosure provides a method of reading data for a data request from one or more requesting agents. In one example the method includes: (1) receiving the data request and semantic information associated with the data request, wherein receiving the data request and semantic information associated with the data request, wherein at least a portion of the semantic information is generated by and is received from the one or more requesting agents, (2) generating reading guidance based on the semantic information, wherein the reading guidance indicates error checking procedures for data provided in response to the request, (3) obtaining data for the data request from data storage according to the reading guidance, wherein the error checking procedures include instructions for determining a type of error checking scheme to employ when obtaining the data.

### BRIEF DESCRIPTION

Reference is now made to the following descriptions taken in conjunction with the accompanying drawings, in which:

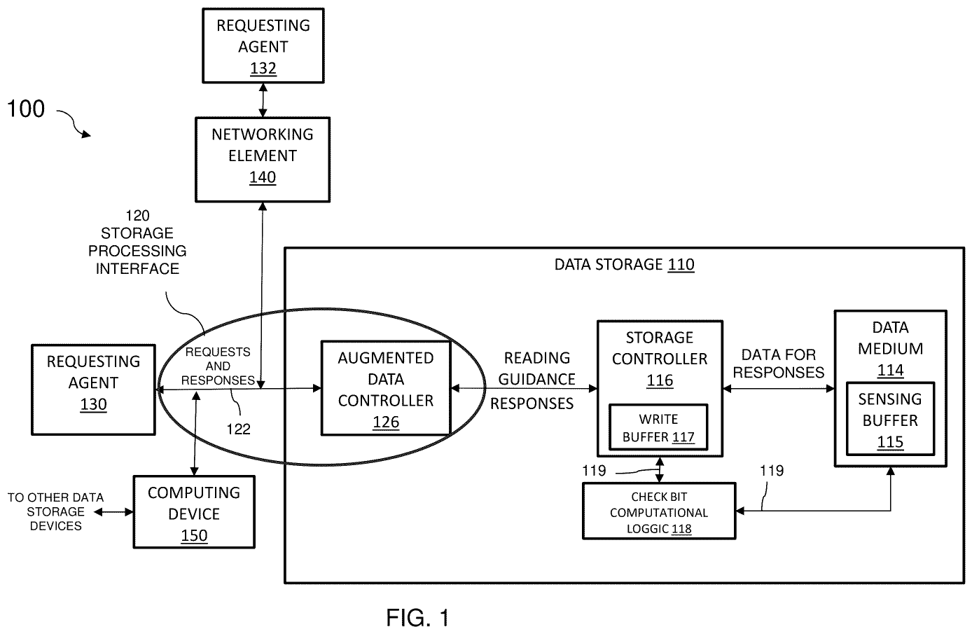

FIG. 1 illustrates a block diagram of an example of a data storage system having a storage processing interface constructed according to the principles of the disclosure;

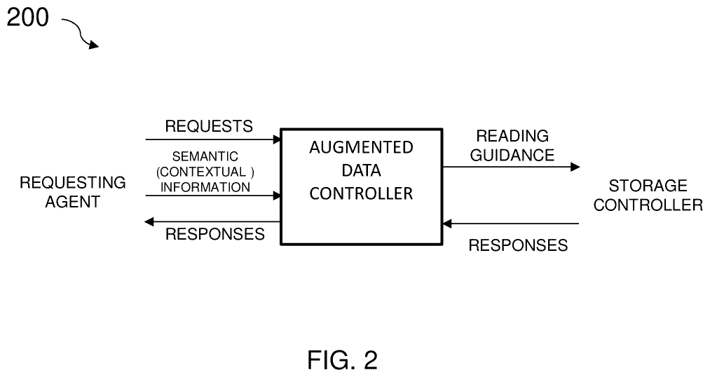

FIG. 2 illustrates a block diagram of an example of an augmented data controller constructed according to the principles of the disclosure;

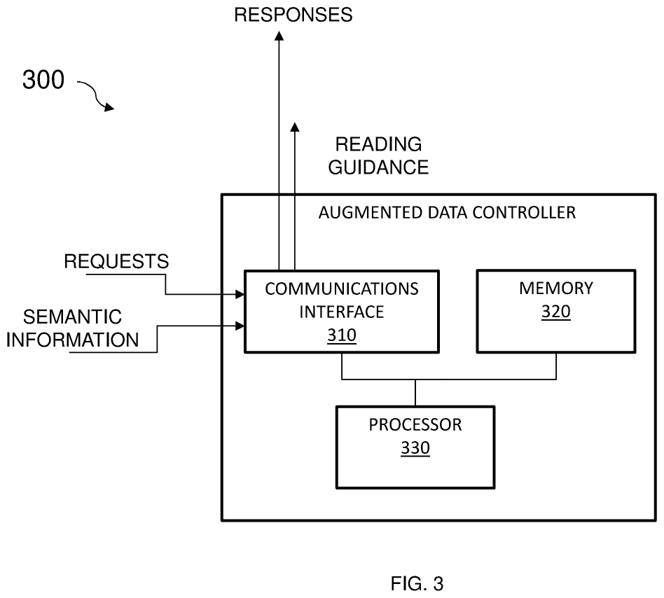

FIG. 3 illustrates a block diagram of another example of an augmented data controller constructed according to the principles of the disclosure; and

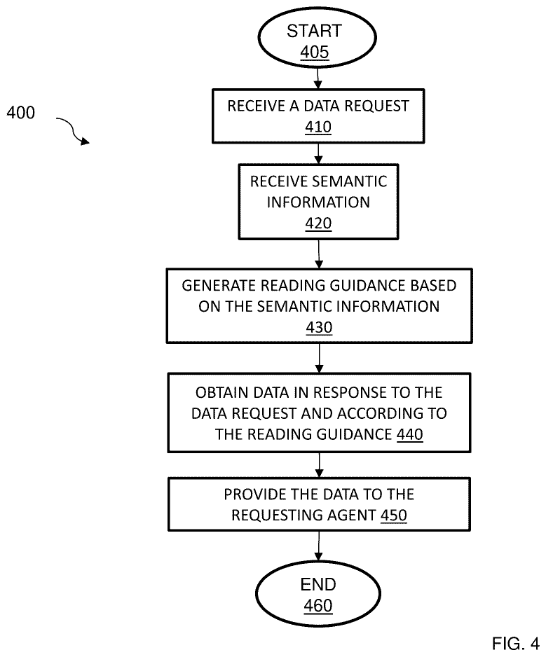

FIG. 4 illustrates a flow diagram of an example method of reading data carried out according to the principles of the disclosure.

### DETAILED DESCRIPTION

Traditional storage controllers perform error checking at a large codeword granularity and access entire codewords regardless of the actual access request granularity. For fine-grained accesses, e.g. 4KB or less, the IO amplification factor caused by accessing entire codewords induces energy efficiency concerns, as many more bits are accessed in the storage media than are used by an application.

Accordingly, the disclosure provides an apparatus, system, and method that increases the power efficiency of reading data from a storage device using, for example, reading guidance. The reading guidance can be generated by requesting agents and may be sent with requests for data. The reading guidance allows software-defined data sizes that are beneficial for saving power when accessing data. The reading guidance can be the result of the requesting agents providing additional contextual information that improves the power efficiency of obtaining data. For example, the requesting agent, or a requestor application executing on the requesting agent, may have knowledge of an optimal data access size, an expected criticality of access latency, knowledge of data which has been recently accessed, or a combination thereof. An optimal data size may be a codeword or even a subset of a codeword. As used herein, a codeword is the smallest unit of data for which check bits can be employed to perform error correction and a subset of a single codeword, or sub-codeword, is a unit of data that is smaller than a codeword.

An augmented data controller is disclosed that provides the reading guidance to a storage controller of a data storage to improve power efficiency when processing data requests, such as fine-grained data requests. The reading guidance can include one or more of an amount of data to read for a data request(s), error checking procedures for data provided in response to the data request(s), or a combination of both. The augmented data controller or logic thereof can be located within the storage controller itself or in another device such as a requesting agent, a networking device, or within a data storage device besides within the storage controller. The logic can also be distributed over multiple devices, such as those just mentioned. The logic of the augmented data controller can be implemented as software, hardware, or a combination thereof. The logic can correspond to one or more algorithms that are directed to perform the various features/functions disclosed herein that increase the power efficiency of reading data from a storage device.

For example, the disclosed features can allow a reduction in power when accessing data by requiring fewer bits and reducing the distance needed to move data. The disclosed features can also provide a performance increase when accessing data compared to existing drives. As such, fewer memory drives may be needed to meet a given performance target, which can also contribute to better overall power efficiency.

FIG. 1 illustrates a block diagram of an example of a data storage system 100 having a storage processing interface constructed according to the principles of the disclosure. Data storage system 100 includes data storage 110, a storage processing interface 120, a requesting agent 130, and/or a networking element 140. The data storage system 100 can also include additional components represented by requesting agent 132 and computing device 150. The data storage 110 includes a data medium 114, a storage controller 116, and check bit computational logic 118.

Data storage 110 is configured to retain digital data in a computer-readable medium, which is represented by data medium 114 in FIG. 1. The data medium 114 can be non-volatile memory, such as flash memory, magnetic disks, such as hard disc drives (HDDs), or another computer readable medium. The flash memory can be, for example, a NAND memory. The data medium 114 can also be a solid-state storage device, such as an SSD, or a DNA data storage device. The data medium 114 includes sensing buffer 115 that is used to temporarily store data in response to a data request before the data is sent to the requestor, such as requesting agent 130. The data medium 114 can have more than one sensing buffer and each of the multiple sensing buffers can process a whole page of data from the data medium 114. Processing by each of the sensing buffers can be done concurrently.

Storage controller 116 is configured to manage communications with the data medium 114, such as communications with the requesting agent 130, using one or more channels or busses. The storage controller 116 can also be configured to provide additional functions for the data medium 114, such as encryption, compression, and error correction. The logic of the storage controller 116 can be implemented as hardware, software, or a combination thereof. The storage controller 116 can be, for example, an application-specific integrated circuit (ASIC) having an embedded processor. Other components or devices may be configured to perform one or more of the functions of the storage controller 116. As such, some of the functionality of the storage controller 116 can be offloaded to another computing device. For example, a computing device coupled to the communication bus 122 may be programmed to perform one or more functions of the storage controller 116. The device can be, for example, a CPU or a GPU that is more efficient at performing the hardware implemented functions of the storage controller 116. Instead of just data storage 110, the computing device can be configured to provide control functions for multiple data storage devices. Computing device 150 is shown in FIG. 1 as an example.

The check bit computational logic 118 is configured to perform error detection to ensure the accuracy of data being obtained in response to a data request. As shown in FIG. 1, the check bit computational logic can be located in the data storage 110. Accordingly, the data storage 110 can further include circuitry 119 for routing control bits to the check bit computational logic 118. The logic, or a portion thereof, can also be located in the requesting agent 130, in the storage controller 116 or can be located in the data medium 114 itself. Thus, error checking and correction can be performed in the data medium 114, such as when only one or more codewords are required to be sent to the storage controller 116. As such, only the desired subset of corrected codewords would need to be sent to the storage controller 116. The check bit computational logic can be hardware software, or a combination thereof.

Storage processing interface 120 is configured to communicatively connect and process communications with the data storage 110 to and from the requesting agent 130 and the networking element 140. The storage processing interface 120 includes a communication bus 122 and an augmented data controller 126. The communication bus 122 is configured to physically connect the data storage 110, the requesting agent 130, and the networking element 140 for communication therebetween. Multiple requesting agents can be coupled to the data storage via the communication bus 122. One or more of the multiple requesting agents, such as requesting agent 130, can be coupled to the communication bus 122 via a networking element, such as networking element 140. FIG. 1 provides an example of a requesting agent 132 in addition to requesting agent 132 that is coupled to the data storage 110 via the networking element 140 and the communication bus 122. The communication bus 122 can be a high-speed interconnect. For example, the communication bus 122 can be a peripheral component interconnect (PCI) bus, a PCI express (PCIe) bus, a compute express link (CXL), an NVLink, or a network. Examples of communications via the communication bus 122 include data requests from the requesting agent 130 to the data storage 110 and data responses from the data storage 110 to the requesting agent 130.

The requesting agent 130 can be a processor, such as a GPU or a CPU. The networking element 140 can be a networking device, such as a network interface card (NIC) or a microprocessor designed for networking. For example, the networking element 140 can be a data processing unit (DPU). The networking element 140 can be configured to map a region of the data medium 114 for access by the networking element 140. For example, the networking element 140 can use User Memory Registration (UMR). The UMR can use one or more of a repeat count, a fixed chunk size, and/or a fixed stride. The UMR can also parse and operate on a list of non-strided items.

The augmented data controller 126 of the storage processing interface 120 is configured to perform operations associated with obtaining data from the data storage 110 for one or more requesting agents, such as requesting agent 130 or networking element 140. As shown in FIG. 1, the augmented data controller 126 can be located within data storage 110. As noted above, the logic of the augmented data controller 126 can also be integrated in another device such as the requesting agent 130, the networking element 140, or within another data storage device besides the data storage 110. The augmented data controller 126 can be integrated in the storage controller 116. The logic can also be distributed over multiple devices, such as those just mentioned. The logic of the augmented data controller 126 corresponds to one or more algorithms that are directed to performing the operations associated with obtaining data from the data storage 110.

The operations include, for example, providing reading guidance to the storage controller 116 that indicates one or more of an amount of data to read for a data request(s), error checking procedures for data provided in response to the data request(s), or a combination of both. The data can include payload data that is produced or consumed by the application and check bits that are used to ensure the data integrity of the payload. A decrease in codeword size can induce an increase in the ratio of a number of check bits to payload data needed for a given error correcting capability. Additionally, an absolute sum of payload data and check bits can decrease with smaller payload sizes, for example, up to a determined limit. Furthermore, the size of the codeword and bits could be dynamically configured for a storage device, e.g. to address an increase in the likelihood of errors over the lifetime of the device. The reading guidance can include instructions to store check bits as payload data and enable processing and correcting of the payload data external to the data storage 110.

The guidance on the amount of data to read determines the number of bytes read into sensing buffer 115. The amount of data can be a whole page of data from the data medium 114 and corresponding check bits for the whole page. The amount of data can also be a smaller amount of data than a whole page of data (less than a whole page) from the data medium 114 and fewer check bits than corresponding check bits for the whole page. The smaller amount of data can be a codeword and the corresponding check bits can be the check bits for that codeword. Instead of a codeword, the smaller amount of data can be a sub-codeword without any check bits. The smaller amount of data can also be, for example, a selected subset of codewords and the corresponding check bits would be the check bits for the selected subset. The subset of codewords can be selected by a command from the one or more requesting agents, such as requesting agent 130. The command can include a preconfigured setting corresponding to a universal mode that is used for the selecting codewords. The command can also include a preconfigured setting used for the selecting that is specific to one or more regions of the data medium. The command can also, or alternatively, include a configuration that is specific for a given set of data requests.

The reading guidance can also include information regarding reading data from the sensing buffer 115. For example, the reading guidance can indicate an amount of data to read from the sensing buffer 115 to the storage controller 116. The amount of data can be based on a type of the data. The amount of data can also be variable, such as, within different portions of the data medium 114 of the data storage 110. The amount of data can be defined by software that is executing on the one or more requesting agents. The executing software can be the software that is generating the data request. The software can define a number of check bits, codeword size, or a combination of both.

The amount of data to read from the sensing buffer 115 to the storage controller 116 can be all of the data in the sensing buffer 115 and the corresponding check bits. The amount of data to read from the sensing buffer 115 to the storage controller 116 can also be less than all the data in the sensing buffer 115. As such, fewer bits may need to be moved between the sensing buffer 115 and the storage controller 116, which would contribute to power efficiency, performance efficiency, or both. The amount of data to read from the sensing buffer 115 can be, for example, a codeword and associated check bits, a subset of a codeword without any check bits, and one or more codewords and the associated error checking bits. The reading guidance can also include error checking procedures for the data being read. The error checking procedures can include instructions for error checking using a Bose-Chaudhuri-Hocquenghem (BCH) or similar checking scheme on the one or more codewords and indicate valid data of the one or more codewords based on results of the error check. The error checking procedures can indicate valid data when no errors are detected via the BCH or similar checking scheme.

Based on the validity of the data of a codeword, reading of the whole sensing buffer 115 and associated check bits can be prevented when an error is detected. Preventing reading of data in all of the sensing buffer 115 can result in a significant power savings.

The error checking procedures noted in the reading guidance can include instructions for determining a type of error checking scheme to employ. The type of error checking scheme can be, for example, based on the amount of data to read from the sensing buffer 115. An example of a type of error checking scheme is a Low-Density-Parity-Check (LDPC) or a similar scheme when the amount of data to read from the sensing buffer 115 is a whole page. The type of error checking scheme can also be based on a type of storage where the data is stored on the data medium. For example, the data medium 114 can include an area of storage denoted as premium storage and an area of storage denoted as standard storage. When the type of storage is premium storage, the type of error checking scheme is amenable to prediction of readable data without checking for errors or amenable to checking using fewer check bits. Accordingly, a premium storage can be used when the type of error checking scheme is for no checking or using a reduced number of check bits. The reading guidance or the storage controller 116 can provide instructions to use premium storage. The augmented data controller 126 can further provide writing directions that indicate a type of storage for writing data, wherein the writing directions indicate standard storage or the premium storage that is used less than the standard storage.

Additionally, the type of error checking scheme can be based on a number of check bits to use for the error checking. The augmented data controller can use a mask to route the number of check bits for the error checking scheme to check bit computational logic 118. Determining the type of error checking scheme can be based on one or more of a previous error checking scheme or results of a previous error checking scheme. For example, the previous type of error checking scheme can be BCH or a similar scheme. When the previous BCH or similar scheme fails, the next error checking scheme can be designated a LDPC or similar checking scheme. The error checking procedures can include submitting a subsequent request to retrieve a whole page and corresponding check bits from the sensing buffer 115 for the error checking when using the LPDC or similar scheme. Advantageously, the error checking procedures can prevent reuse of the sensing buffer 115 and maintain accessibility thereof until the retrieved whole page passes being checked. The data medium 114 can include multiple sensing buffers that are each configured for processing a whole page. As such, the error checking procedures can include instructions to allocate usage of the multiple sensing buffers for concurrent processing.

The error checking procedures can include steps to perform if the LPDC or similar scheme fails. For example, the procedures could include instructions for adjusting the voltage threshold for reading the data. The error checking procedures can also include higher level instructions for obtaining the data if the error checking schemes fail. For example, the error checking procedures can include instructions to check another location besides the data storage 110 to obtain the data when there is an error in obtaining the data. For example, a copy of the data could be maintained in another storage medium or designated computing device, such as computing device 150. Accordingly, the desired data may still be obtained even if an error is determined according to the error checking procedures.

The type of error checking scheme can be null or no error checking scheme can be applied depending on, for example, one or more error checking factors. The one or more error checking factors can be based on availability of check bits, the amount of data to read, or a combination of both. The amount of data to read, for example, can be a sub-codeword, which is smaller than the minimum granularity that can be checked with check bits.

The one or more error checking factors can also be based on one or more predictive models. The one or more predictive models can be a statistical model. The statistical model can be based on information corresponding to the validity of the data and the information can be from the storage controller 116. The information can indicate, for example, one or more of: 1) when a scan of the data medium, that at least includes the data, was performed, (2) wear of the data medium 114, or (3) recent error rates.

The information can correspond to the context of the data to read, wherein different threshold levels of certainty can be used for the error checking procedure according to the context. The information can also be directed to saving power for processing reads from the sensing buffer 115. Saving of power to read corresponds to a burst of reads or writes according to an application executing on the one or more requesting agents, including requesting agent 130. Regardless the type of predictive models, the one or more predictive models considered can be AI-based predictive models, non-AI based predictive models, or a combination of both.

The reading guidance can further include one or more policies to apply for managing the data medium 114 of the data storage 110. The one or more policies are communicated from the requesting agent and stored in the data medium 114 or the storage controller 116 for tracking purposes. At least one of the one or more policies can be applied to a set of tracked memory regions of the data medium 114. At least one of the one or more policies can be applicable between one command that declares the set of tracked memory regions open for a particular usage, and a second command that declares that same or different set of tracked memory regions closed for a particular usage. Each of the one or more policies can avoid a refresh or garbage collection or erasure or writing while open. Writes to the data medium 114, for example, can be deferred by buffering the data to be written in buffers. The buffers are sufficiently sized to hold the date for deferring the writes and, as such, can be larger than typical write buffers used with memory devices. The buffers for deferring are located in the data storage 110 and can be located, for example, in the storage controller 116 or the data medium 114. Write buffer 117 provides an example of a buffer that can be used for deferring. Policies may be used to specify whether refresh, garbage collection, erasure, or writing is temporarily suspended to allow other accesses to the data medium 114, which may be a high or higher priority to continue without being inhibited due to structural limitations on performing different kinds of operations, like erase and read, concurrently within a same independent region within the data medium 114. For example, the data medium 114 can be a NAND memory having different planes that allow only one class of operations to be performed at a time and, therefore, prohibit two different types of operations being performed concurrently within a storage die. Accordingly, the one or more policies can provide guidance to increase the efficiency of the data storage.

Furthermore, decisions could be made across storage devices. For example, in order to avoid disrupting latency for a particular request, a request could be redirected to a different device that does not have a conflict. This could enable a conflicting operation to proceed, thereby avoiding a power-inefficient suspend. This could be facilitated by a soft error code that communicates to high-level software that while efficient access to data in this device may soon be restored, getting from another replicated source could be more time efficient. The other source can be, for example, computing device 150.

FIG. 2 illustrates a block diagram of an example of an augmented data controller 200 constructed according to the principles of the disclosure. The augmented data controller 200 is configured to perform one or more operations associated with obtaining data from data storage for a requesting agent. The augmented data controller 200 provides an example of the augmented data controller 126 of FIG. 1.

The augmented data controller 200 receives one or more data requests from a requesting agent that are directed to a storage controller of a data storage. Additionally, the augmented data controller 200 receives one or more data responses from the storage controller that are directed to the requesting agent for the one or more data requests. In addition to data requests, the augmented data controller 200 is also configured to receive semantic information from the requesting agent. The semantic information provides contextual information associated with the data request that is directed to improving the power efficiency of obtaining data. For example, the semantic information can indicate the codeword size for reading.

The augmented data controller 200 also includes one or more processors that are configured to perform one or more operations. The operations include, for example, providing reading guidance to a storage controller associated with the data storage, wherein the reading guidance is generated from the semantic information provided by the requesting agent. As such, the augmented data controller 200 is configured to generate reading guidance that allows power savings when reading data compared to existing memory systems.

FIG. 3 illustrates a block diagram of another example of an augmented data controller 300 constructed according to the principles of the disclosure. The augmented data controller 300 of FIG. 3 includes one or more communications interface, represented by communications interface 310, one or more memories, represented by memory 320, and one or more processors, represented by processor 330. The various components of the augmented data controller 300 can communicate via wireless or wired conventional connections. As noted above, a portion of the augmented data controller 300 can be located at one or more locations.

Communications interface 310 is configured to transmit and receive data. For example, communications interface 310 can receive requests, semantic information, and commands from one or more requesting agents. The semantic information is a word or multiple words that provide semantic guidance for processing data reading for data requests. The semantic information can include the commands and/or additional contextual information that may correspond to data request and/or represent policies for processing data requests and/or data responses; especially reading data from the data medium for data responses. Communications from the requesting agents can be received via a communications bus, such as communication bus 122 of FIG. 1. The communications interface 310 can also receive responses from and provide reading guidance to a storage controller, such as storage controller 116 of FIG. 1.

Memory 320 can be configured to store a series of operating instructions that direct the operation of processor 330 when initiated, including supporting code representing one or more algorithms for processing data requests and responses using reading guidance. Memory 320 is a non-transitory computer-readable medium. Multiple types of memory can be used for the data storage systems and memory 320 can be distributed.

Processor 330 can be one or more processors. Processor 330 can be a combination of processor types, such as a CPU, a GPU, a single instruction multiple data (SIMD) processor, or other processor types. Processor 330 can be a virtual process supported by a processing unit. Processor 330 can be dedicated circuitry within a processor. Processor 330 can be a code process running on a processor. Processor 330 can be configured to, for example, generate reading guidance for processing data requests.

Processor 330 can be an integrated circuit. In some aspects, processor 330, communications interface 310, memory 320, or various combinations thereof, can be an integrated circuit. Processor 330 includes the logic to communicate with communications interface 310 and memory 320, and perform the functions described herein, including generating reading guidance from the received semantic information from requesting agents.

FIG. 4 illustrates a flow diagram of an example method 400 of reading data carried out according to the principles of the disclosure. One or more of the steps of method 400 can be carried out by an augmented data controller and/or storage processing interface, such as storage processing interface 120 and augmented data controllers 126, 200, and 300 as disclosed herein. Method 400 begins at step 405.

In step 410, a data request is received. The data request can be from a requesting agent and directed to a storage controller of a data storage. An augmented data controller can receive the data request from the requesting agent.

In step 420, semantic information is received. The semantic information provides contextual information associated with the data request. The semantic information can also be received by the augmented data controller from the requesting agent.

Reading guidance for obtaining data for the data request is generated in step 430 based on the semantic information. Generating the reading guidance can include generating commands and instructions for the storage controller based on the semantic information. The generating can also include providing the reading guidance in the format or protocol used by the storage controller. The semantic information may be in a proper format when received. The reading guidance can be generated by the augmented data controller.

In step 440 the data is obtained according to the reading guidance. The data can be obtained from a data medium, such as data medium 114. The data could be obtained from a replicated source, such as computing device 150, according to the reading guidance.

Method 400 continues to step 450 wherein the data is provided to the requesting agent. The data can be provided via the communication bus. Method 400 then ends in step 460.

A portion of the above-described apparatus, systems or methods may be embodied in or performed by various digital data processors or computers, wherein the computers are programmed or store executable programs of sequences of software instructions to perform one or more of the steps of the methods. The software instructions of such programs may represent algorithms and be encoded in machine-executable form on non-transitory digital data storage media, e.g., magnetic or optical disks, random-access memory (RAM), magnetic hard disks, flash memories, and/or read-only memory (ROM), to enable various types of digital data processors or computers to perform one, multiple or all of the steps of one or more of the above-described methods, or functions, systems or apparatuses described herein. The data storage media can be part of or associated with digital data processors or computers.

The digital data processors or computers can be comprised of one or more GPUs, one or more CPUs, one or more of other processor types, or a combination thereof. The digital data processors and computers can be located proximate to each other, proximate to a user, in a cloud environment, a data center, or located in a combination thereof. For example, some components can be located proximate to the user, and some components can be located in a cloud environment or data center.

The GPUs can be embodied on one semiconductor substrate, included in a system with one or more other devices such as additional GPUs, a memory, and a CPU. The GPUs may be included on a graphics card that includes one or more memory devices and is configured to interface with a motherboard of a computer. The GPUs may be integrated GPUs (iGPUs) that are co-located with a CPU on one chip. Configured or configured to means, for example, designed, constructed, or programmed, with the necessary logic and/or features for performing a task or tasks.

Portions of disclosed examples or embodiments may relate to computer storage products with a non-transitory computer-readable medium that have program code thereon for performing various computer-implemented operations that embody a part of an apparatus, device or carry out the steps of a method set forth herein. Non-transitory used herein refers to all computer-readable media except for transitory, propagating signals. Examples of non-transitory computer-readable media include, but are not limited to: magnetic media such as hard disks, floppy disks, and magnetic tape; optical media such as CD-ROM disks; magneto-optical media such as floppy disks; and hardware devices that are specially configured to store and execute program code, such as ROM and RAM devices. Examples of program code include both machine code, such as produced by a compiler, and files containing higher level code that may be executed by the computer using an interpreter.

In interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

Those skilled in the art to which this application relates will appreciate that other and further additions, deletions, substitutions, and modifications may be made to the described embodiments. It is also to be understood that the terminology used herein is for the purpose of describing particular embodiments only, and is not intended to be limiting, since the scope of the present disclosure will be limited only by the claims. Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, a limited number of the exemplary methods and materials are described herein.

Various aspects of the disclosure can be claimed including the apparatuses, systems, and methods disclosed in the Summary. Each of those aspects can have one or more of the following additional elements in combination: Element 1: wherein at least a portion of the reading guidance are generated by and are received from the one or more requesting agents. Element 2: wherein the amount of data to read is the amount of data to read into a sensing buffer in a data medium of the data storage. Element 3: wherein the reading guidance further indicates an amount of data to read from the sensing buffer to the storage controller. Element 4: wherein the amount of data to read from the sensing buffer to the storage controller is all the data in the sensing buffer and the corresponding check bits. Element 5: wherein the amount of data to read from the sensing buffer to the storage controller is less than all the data in the sensing buffer. Element 6: wherein the amount of data to read from the sensing buffer to the storage controller is a codeword and associated check bits. Element 7: wherein the amount of data to read from the sensing buffer to the storage controller is a subset of a codeword, without any check bits. Element 8: wherein the amount of data is a whole page of data from the data medium and corresponding check bits for the whole page. Element 9: wherein the amount of data is a smaller amount of data than a whole page of data from the data medium and fewer check bits than corresponding check bits for the whole page. Element 10: wherein the smaller amount of data is a codeword and corresponding check bits for the codeword. Element 11: wherein the smaller amount of data is a selected subset of codewords for the selected subset. Element 12: wherein the subset of codewords is selected by a command from the one or more requesting agents. Element 13: wherein the command includes a preconfigured setting corresponding to a universal mode that is used for the selecting. Element 14: wherein the command includes a preconfigured setting used for the selecting that is specific to one or more regions of the data medium. Element 15: wherein the command includes a configuration that is specific for a given set of requests. Element 16: wherein the smaller amount of data is a sub-codeword without check bits. Element 17: wherein the amount of data includes one or more codewords and the error checking procedures include instructions for error checking using a Bose-Chaudhuri-Hocquenghem (BCH) or similar checking scheme on the one or more codewords and indicate valid data of the one or more codewords based on results of the error check. Element 18: wherein the error checking procedures indicate the valid data when no errors are detected via the BCH or similar checking scheme. Element 19: wherein based on the validity of the data of the codeword, reading of a whole sensing buffer and associated check bits are prevented resulting in a significant power savings compared to reading the whole sensing buffer. Element 20: wherein the error checking procedures include instructions for determining a type of error checking scheme to employ. Element 21: wherein the determining the type of error checking scheme is based on the amount of data to read. Element 22: wherein the type of error checking scheme is a Low-Density-Parity-Check (LDPC) or a similar scheme when the amount of data to read is a whole page. Element 23: wherein the error checking scheme is a Low-Density-Parity-Check (LDPC) or a similar scheme and the error checking procedures include additional instructions to obtain the data when the error checking scheme indicates an error. Element 24: wherein the determining the type of error checking scheme is based on a type of storage where the data is stored, wherein the type of storage includes premium and standard storage. Element 25: wherein when the type of storage is premium storage, the type of error checking scheme is amenable to prediction of readable data without checking for errors or checking using fewer check bits. Element 26: wherein the determination of the type of error checking scheme is based on a number of check bits to use. Element 27: wherein a mask is used to route the number of check bits for the error checking scheme to check bit computational logic. Element 28: wherein a premium storage is used when the type of error checking scheme is for no checking or using a reduced number of check bits. Element 29: wherein the reading guidance or the storage controller provides instructions to use premium storage. Element 30: wherein the determining the type of error checking scheme is based on one or more of a previous error checking scheme or results of a previous error checking scheme. Element 31: wherein the type of error checking scheme is a LDPC or similar scheme when results of a previous BCH or similar scheme on a codeword fails. Element 32: wherein the error checking procedures further include submitting a subsequent request to retrieve a whole page and corresponding check bits from the sensing buffer for the error checking using the LPDC or similar scheme. Element 33: wherein the error checking procedures further include preventing reuse of the sensing buffer and maintain accessibility of the sensing buffer until the page passes being checked. Element 34: wherein the data medium includes multiple sensing buffers for each whole page and the error checking procedures include instructions to allocate usage of the multiple sensing buffers for concurrent processing. Element 35: wherein the type of error checking scheme is null and no error checking scheme is applied based on one or more error checking factors. Element 36: wherein the one or more error checking factors are based on availability of check bits. Element 37: wherein the amount of data to read is a sub-codeword. Element 38: wherein the one or more error checking factors are based on one or more predictive models. Element 39: wherein the one or more predictive models include a statistical model. Element 40: wherein the one or more predictive models is an AI-based predictive model. Element 41: wherein the one or more predictive models include a combination of a predictive model and an AI-based predictive model. Element 42: wherein the statistical model is based on information corresponding to the validity of the data. Element 43: wherein the information is from the storage controller and indicates one or more of: 1) when a scan of the data medium, that at least includes the data, was performed, 2) indicates wear of the media, or 3) tracks recent error rates. Element 44: wherein the statistical model is based on information corresponding to context of the data to read. Element 45: wherein different threshold levels of certainty are used for the error checking procedure according to the context. Element 46: wherein the statistical model is based on information regarding saving power for processing the read. Element 47: wherein the saving of power corresponds to a burst of reads or writes according to an application executing on the one or more requesting agents. Element 48: wherein the reading guidance further includes one or more policies to apply for managing a data medium of the data storage. Element 49: where the one or more policies are communicated from the requestor and stored in the data medium or the storage controller for tracking purposes. Element 50: wherein at least one of the one or more policies is applied to a set of tracked memory regions. Element 51: where the at least one of the one or more policies is applicable between one command that declares the set of tracked memory regions open for a particular usage, and a second command that declares that same or different set of tracked memory regions closed for a particular usage. Element 52: wherein the one or more policies include avoiding a refresh or garbage collection while open. Element 53: wherein the one or more policies include avoiding a write while open and storing the data to write in a write buffer. Element 54: wherein the one or more policies include avoiding a write while open and storing the data to write in a write buffer. Element 55: wherein the amount of data is variable. Element 56: wherein the amount of data is variable within different portions of a data medium of the data storage. Element 57: wherein amount of data is defined by software that is executing on the one or more requesting agents and is the software generating the request. Element 58: wherein the amount of data is based on a type of the data. Element 59: wherein the software defines a number of check bits, codeword size, or a combination of both. Element 60: wherein the data includes payload data and check bits and the reading guidance further include instructions to store check bits as payload data and enabling processing and correcting external to the data storage. Element 61: wherein a ratio of a number of check bits to payload data needed for a given error correcting capability increases with decreasing codeword size and an absolute sum of payload data and check bits decreases with smaller payload sizes up to a determined limit. Element 62: wherein the operations further include writing directions that indicate a type of storage for writing data, wherein the writing directions indicate standard storage or premium storage that is used less than the standard storage. Element 63: wherein at least a portion of the augmented data controller is located in at least one of the one or more requesting agents, the storage controller, the data storage, or a networking device. Element 64: wherein the data storage includes check bit computational logic. Element 65: wherein at least a portion of the check bit computational logic is located in a data medium of the data storage. Element 66: wherein when only one or more codewords are required to be sent to the storage controller, error checking and correction can be performed in the data medium and only the desired subset of corrected codewords are sent to the storage controller. Element 67: wherein at least a portion of the check bit computational logic is located in the storage controller of the data storage. Element 68: wherein at least a portion of the check bit computational logic is located at least one of the one or more requesting agents. Element 69: wherein the check bit computational logic is hardware, software, or a combination thereof. Element 70: wherein the augmented data controller is located in the storage controller. Element 71: wherein the augmented data controller is located in at least one of the requesting agents. Element 72: wherein the at least one of the requesting agents is a GPU or a CPU. Element 73: wherein the communication bus is a PCIe bus. Element 74: further comprising a data medium that stores the data and at least one sensing buffer for each whole page of data stored in the data medium. Element 75: further comprising more than one sensing buffer for at least one of the whole pages of data stored in the data medium. Element 76: further comprising check bit computational logic. Element 77: wherein at least a portion of the check bit computational logic is located in the data medium. Element 78: wherein at least a portion of the check bit computational logic is located in the storage controller. Element 79: further comprising circuitry for routing control bits to the check bit computational logic. Element 80: further comprising a computing device coupled to the communication bus and configured to perform one of more functions of the storage controller of the data storage. Element 81: further comprising a computing device coupled to the communication bus and configured to provide back-up storage for at least some of the data of the data medium.

What is claimed:

1. An augmented data controller configured to perform one or more operations associated with obtaining data from data storage for one or more requesting agents, the operations comprising:
providing reading guidance to a storage controller associated with the data storage, wherein the reading guidance indicates error checking procedures for data provided in response to the request.

2. The augmented data controller as recited in claim 1, wherein the error checking procedures include instructions for determining a type of error checking scheme to employ.

3. The augmented data controller as recited in claim 2, wherein determining the type of error checking scheme is based on an amount of the data to read.

4. The augmented data controller as recited in claim 3, wherein the type of error checking scheme is a Low-Density-Parity-Check (LDPC) or a similar scheme when the amount of the data to read is a whole page.

5. The augmented data controller as recited in claim 2, wherein the error checking scheme is a Low-Density-Parity-Check (LDPC) or a similar scheme and the error checking procedures include additional instructions to obtain the data when the error checking scheme indicates an error.

6. The augmented data controller as recited in claim 2, wherein determining the type of error checking scheme is based on a type of the data storage where the data is stored, wherein the type of the data storage includes premium and standard storage.

7. The augmented data controller as recited in claim 6, wherein when the type of the data storage is premium storage and the type of error checking scheme is amenable to prediction of readable data without checking for errors or checking using fewer check bits.

8. The augmented data controller as recited in claim 2, wherein determining the type of error checking scheme is based on a number of check bits to use.

9. The augmented data controller as recited in claim 8, wherein a mask is used to route the number of the check bits for the error checking scheme to check bit computational logic.

10. The augmented data controller as recited in claim 2, wherein a premium storage is used when the type of error checking scheme is for no checking or using a reduced number of check bits and the reading guidance or the storage controller provides instructions to use premium storage.

11. The augmented data controller as recited in claim 2, wherein determining the type of error checking scheme is based on one or more of a previous error checking scheme or results of a previous error checking scheme.

12. The augmented data controller as recited in claim 11, wherein the type of error checking scheme is a Low-Density-Parity-Check (LDPC) or similar scheme when results of a previous BCH or similar checking scheme on a codeword fails, and the error checking procedures further include submitting a subsequent request to retrieve a whole page and corresponding check bits from a sensing buffer of a data medium of the data storage for the error checking using the LDPC or similar scheme.

13. The augmented data controller as recited in claim 12, wherein the error checking procedures further include preventing reuse of the sensing buffer and maintain accessibility of the sensing buffer until the whole page passes being checked.

14. The augmented data controller as recited in claim 12, wherein the data medium includes multiple sensing buffers for each whole page and the error checking procedures include instructions to allocate usage of the multiple sensing buffers for concurrent processing.

15. The augmented data controller as recited in claim 2, wherein the type of error checking scheme is null and no error checking scheme is applied based on one or more error checking factors.

16. The augmented data controller as recited in claim 15, wherein the one or more error checking factors are based on availability of check bits and an amount of data to read is a sub-codeword.

17. The augmented data controller as recited in claim 15, wherein the one or more error checking factors are based on one or more predictive models.

18. The augmented data controller as recited in claim 17, wherein the one or more predictive models is at least one statistical model, at least one AI-based predictive model, or a combination of an AI-based predictive model with another type of predictive model.

19. The augmented data controller as recited in claim 18, wherein the at least one statistical model is based on information corresponding to validity of the data.

20. The augmented data controller as recited in claim 19, wherein the information is from the storage controller and indicates one or more of: 1) when a scan of a data medium of the data storage that includes the data was performed, 2) indicates wear of the data medium, or 3) tracks recent error rates.

21. The augmented data controller as recited in claim 18, wherein the at least one statistical model is based on information corresponding to context of the data to read.

22. The augmented data controller as recited in claim 21, wherein different threshold levels of certainty are used for the error checking procedure according to the context.

23. The augmented data controller as recited in claim 18 wherein the at least one statistical model is based on information regarding saving power for processing reads of a sensing buffer of a data medium of the data storage.

24. The augmented data controller as recited in claim 23, wherein the saving of the power corresponds to a burst of reads or writes according to an application executing on the one or more requesting agents.

25. A storage processing interface, comprising:
a communication bus; and
an augmented data controller connected to the communication bus and configured to perform one or more operations associated with obtaining data from data storage for a request from one or more requesting agents coupled to the communication bus, the operations including:
providing reading guidance to a storage controller associated with the data storage, wherein the reading guidance indicates error checking procedures for the data provided in response to the request.

26. The storage processing interface as recited in claim 25, wherein the communication bus is a PCIe bus.

27. The storage processing interface as recited in claim 25, wherein the error checking procedures include instructions for determining a type of error checking scheme to employ based on an amount of data to read.

28. The storage processing interface as recited in claim 27, wherein determining the type of error checking scheme is based on a type of storage where the data is stored, a number of check bits to use, or on one or more of a previous error checking scheme or results of a previous error checking scheme.

29. A method of reading data for a data request from one or more requesting agents, comprising:
receiving the data request and semantic information associated with the data request, wherein at least a portion of the semantic information is generated by and is received from the one or more requesting agents;
generating reading guidance based on the semantic information, wherein the reading guidance indicates error checking procedures for data provided in response to the request; and
obtaining the data for the data request from data storage according to the reading guidance, wherein the error checking procedures include instructions for determining a type of error checking scheme to employ when obtaining the data.

30. The method as recited in claim 29, further comprising determining the type of error checking scheme based on a type of storage where the data is stored, a number of check bits to use, or on one or more of a previous error checking scheme or results of a previous error checking scheme.
